(19) United States
(12) Patent Application Publication
(10) Pub. No.: US 2024/0034064 A1
(43) Pub. Date: Feb. 1, 2024

(54) INKJET HEAD AND INKJET PRINTING APPARATUS INCLUDING THE SAME

(71) Applicant: Samsung Display Co., LTD., Yongin-si (KR)

(72) Inventor: Yoshiaki SAKAMOTO, Yongin-si (KR)

(21) Appl. No.: 18/352,048

(22) Filed: Jul. 13, 2023

(30) Foreign Application Priority Data
Jul. 28, 2022 (KR) 10-2022-0094185

(51) Int. Cl. B41J 2/14; B41J 2/16; H10N 10/10; C09D 11/38; H05B 6/36

(52) U.S. Cl. CPC B41J 2/1433; B41J 2/1623; H10N 10/10; C09D 11/38; H05B 6/36; B41J 2202/16

(57) ABSTRACT

An inkjet head includes: an ink supply part configured to supply an ink; a nozzle plate connected to the ink supply part and having a nozzle configured to drop the ink provided from the ink supply part; a nozzle plate heating part adjacent to the nozzle plate and configured to heat the nozzle plate; and an insulation member between the nozzle plate and the ink supply part.

### CROSS-REFERENCE TO RELATED APPLICATION

The application claims priority to and the benefit of Korean patent application No. 10-2022-0094185, filed on Jul. 28, 2022, in the Korean Intellectual Property Office, the entire disclosure of which is incorporated herein by reference.

### BACKGROUND

### 1. Field

Aspects of embodiments of the present disclosure relate to an inkjet head and an inkjet printing apparatus including the same.

### 2. Description of the Related Art

Recently, as interest in information displays increases, research and development of display devices has been continuously conducted.

### SUMMARY

Embodiments of the present disclosure provide an inkjet head and an inkjet printing apparatus including the same in which an ink is stably sprayed onto a substrate through the inkjet head and the uniformity of light emitting elements dispersed in the sprayed ink is ensured.

In accordance with an embodiment of the present disclosure, an inkjet head includes: an ink supply part configured to supply an ink; a nozzle plate connected to the ink supply part and having a nozzle configured to drop the ink provided from the ink supply part; a nozzle plate heating part adjacent to the nozzle plate and configured to heat the nozzle plate; and an insulation member between the nozzle plate and the ink supply part.

The inkjet head may further include a first adhesive insulator between the nozzle plate and the insulation member.

The inkjet head may further include a pressure actuator in the ink supply part and configured to vibrate the ink in the nozzle.

The inkjet head may further include a second adhesive insulator between the insulation member and the ink supply part.

The first adhesive insulator and the second adhesive insulator may include an epoxy adhesive.

The insulation member may include at least one of glass and silica fiber.

The nozzle plate heating part may include a heater on one surface of the nozzle plate.

The nozzle plate heating part may include a Peltier module between the nozzle plate and the insulation member.

A low temperature surface of the Peltier module may face the insulation member, and a high temperature surface of the Peltier module may face the nozzle plate.

The nozzle plate heating part may include an induction heating device on a bottom surface of the nozzle plate, and the induction heating device may include a coil.

The nozzle plate heating part may include: electrode terminals electrically connected to the nozzle plate; and an electrode control part configured to apply power to the electrode terminals.

The ink may include at least one of a light emitting element, a conductor metal particle, and a light conversion particle. The light emitting element may include a first semiconductor layer, a second semiconductor layer, and an active layer between the first semiconductor layer and the second semiconductor layer.

The nozzle plate may include a conductive material. A thermal conductivity of the insulation member may be lower than a thermal conductivity of the nozzle plate.

In accordance with another embodiment of the present disclosure, an inkjet printing apparatus includes: a stage configured to receive a substrate thereon; an inkjet head configured to drop ink on the substrate; and a reservoir configured to store the ink. The inkjet head includes: an ink supply part configured to be supplied with the ink from the reservoir; a nozzle plate connected to the ink supply part and having a nozzle configured to drop the ink provided from the ink supply part; a nozzle plate heating part adjacent to the nozzle plate and configured to heat the nozzle plate; and an insulation member between the nozzle plate and the ink supply part.

The inkjet printing apparatus may further include a pressure actuator in the ink supply part and configured to vibrate the ink in the nozzle.

The inkjet printing apparatus may further include: a first adhesive insulator between the nozzle plate and the insulation member; and a second adhesive insulator between the insulation member and the ink supply part.

The first adhesive insulator and the second adhesive insulator may include an epoxy adhesive.

The nozzle plate heating part may include a heater on one surface of the nozzle plate.

The nozzle plate heating part may include an induction heating device including a coil.

The nozzle plate heating part may include a Peltier module between the nozzle plate and the insulation member.

In the inkjet head and the inkjet printing apparatus including the same in accordance with embodiments of the present disclosure, an ink including light emitting elements can be stably dropped through a nozzle.

Also, in the inkjet head and the inkjet printing apparatus including the same in accordance with embodiments of the present disclosure, uniform dispersibility of the light emitting elements in the ink provided to the nozzle can be ensured, and the ink containing a uniform number of light emitting elements can be dropped.

### BRIEF DESCRIPTION OF THE DRAWINGS

Embodiments of the present disclosure will now be described more fully hereinafter with reference to the accompanying drawings; however, the present disclosure may be embodied in different forms and should not be construed as limited to the embodiments set forth herein. Rather, these embodiments are provided so that this disclosure will be thorough and complete and will fully convey the scope of the present disclosure to those skilled in the art.

FIG. 1 is a perspective view of an inkjet printing apparatus in accordance with an embodiment of the present disclosure.

FIG. 2 is a sectional view of the inkjet printing apparatus shown in FIG. 1.

FIG. 3 is a sectional view illustrating an inkjet head in accordance with a comparative example.

FIG. 4A is a graph showing pressure loss in a nozzle according to viscosity of an ink.

FIG. 4B is a graph showing drop in velocity of the ink according to viscosity of the ink.

FIG. 5 illustrates an example of an inkjet head in accordance with an embodiment of the present disclosure.

FIG. 6 illustrates an example of driving of the inkjet head shown in FIG. 5.

FIG. 7 illustrates an insulation member included in the inkjet head shown in FIG. 5 according to an embodiment.

FIG. 8 illustrates a nozzle plate heating part included in the inkjet head shown in FIG. 5 according to an embodiment.

FIG. 9 illustrates a nozzle plate heating part included in the inkjet head shown in FIG. 5 according to an embodiment.

FIG. 10 illustrates a nozzle plate heating part included in the inkjet head shown in FIG. 5 according to an embodiment.

FIG. 11 illustrates the nozzle plate heating part included in the inkjet head shown in FIG. 5 according to an embodiment.

FIG. 12 is a view of an example of a light emitting element included in an ink deposited from a nozzle shown in FIG. 5.

### DETAILED DESCRIPTION

Hereinafter, embodiments of the present disclosure will be described in more detail with reference to the accompanying drawings. It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of,” when preceding a list of elements, modify the entire list of elements and do not modify the individual elements of the list. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

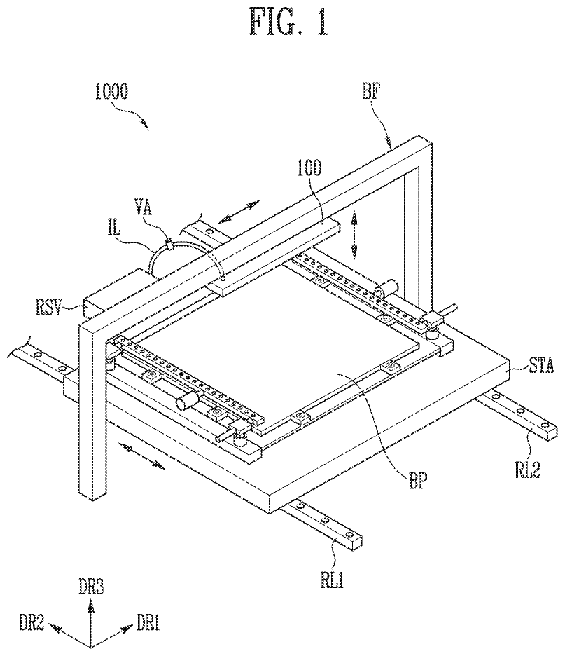

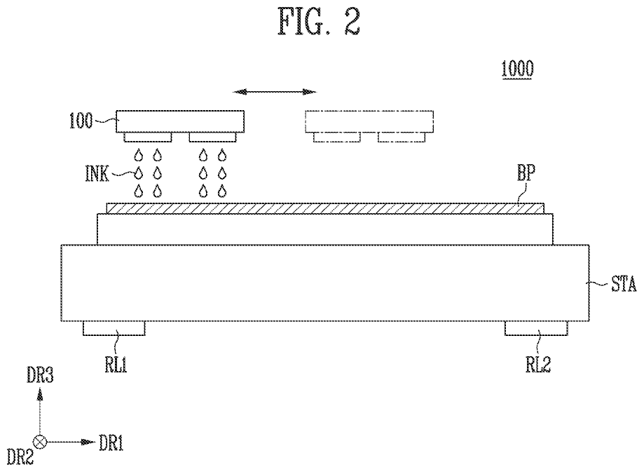

FIG. 1 is a perspective view of an inkjet printing apparatus 1000 in accordance with an embodiment of the present disclosure. FIG. 2 is a sectional view of the inkjet printing apparatus 1000 shown in FIG. 1.

Referring to FIG. 1, the inkjet printing apparatus 1000 may include an inkjet head 100, a base substrate BP, a stage STA, and a reservoir RSV.

In FIG. 1, a first direction DR1, a second direction DR2, and a third direction DR3 are defined. The first direction DR1 and the second direction DR2 are directions which are on the same plane and are orthogonal to each other, and the third direction DR3 is a direction perpendicular to each of the first direction DR1 and the second direction DR2. The first direction DR1 may be understood to be a lateral direction in the drawing, the second direction DR2 may be understood to be a longitudinal direction in the drawing, and the third direction DR3 may be understood to be an upper or lower direction in the drawing.

In an embodiment, the stage STA may support the base substrate BP and may be formed of a rigid material. However, the material of the stage STA is not limited thereto. The stage STA may have a rectangular parallelepiped shape, but the shape of the stage STA is not limited thereto.

In an embodiment, the base substrate BP may be disposed on the stage STA. The base substrate BP may be a unit display substrate or may be a mother substrate before being cut and divided into a plurality of unit display substrates. The base substrate BP may be one sheet of substrate or may include a plurality of stacked substrates.

In an embodiment, the base substrate BP may include a plurality of sub-pixel areas. In an example, the plurality of sub-pixel areas may include areas in which sub-pixels, such as a red pixel R, a green pixel G, and a blue pixel B, are disposed.

In an embodiment, the inkjet printing apparatus 1000 may spray an ink (e.g., a predetermined ink) INK onto the base substrate BP by using the inkjet head 100.

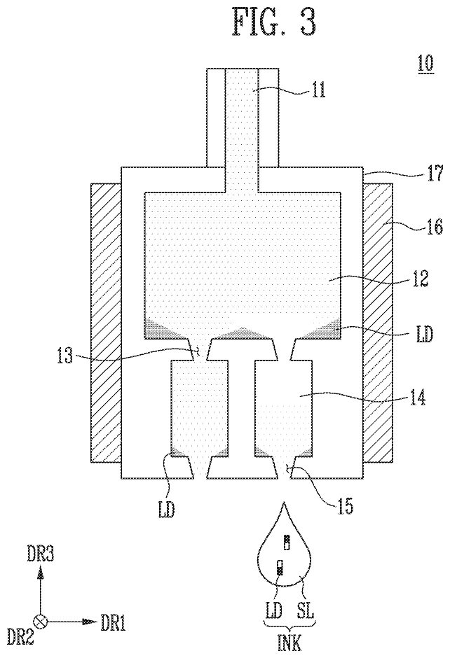

In an embodiment, the inkjet head 100 may spray, drop (or deposit), or print the ink INK including a light emitting element LD (see, e.g., FIG. 3) onto the base substrate BP.

In an embodiment, the inkjet printing apparatus 1000 may include a first rail RL1 and a second rail RL2, both of which extend in the second direction DR2, and the stage STA may be disposed on the first rail RL1 and the second rail RL2. The stage STA may be moved on the first rail RL1 and the second rail RL2 by a separate moving member. While the stage STA passes through (e.g., passes under) the inkjet head 100, the ink INK may be sprayed onto the base substrate BP that is on the top of the stage STA. Although a structure in which the stage STA is moved is illustrated in the drawings, the present disclosure is not limited thereto. In other embodiments, the inkjet head 100 may be moved while the stage STA is fixed. The inkjet head 100 may be held on a frame disposed on (or over) the first rail RL1 and the second rail RL2.

In an embodiment, a width of the base substrate BP in the first direction DR1 may be greater than a width of the inkjet head 100 in the first direction DR1. The inkjet head 100 may be moved in the first direction DR1, thereby spraying the ink INK onto the entire base substrate BP. However, the present disclosure is not limited thereto, and the inkjet head 100 may be located at the outside of the first rail RL1 and the second rail RL2 and then moved in the first direction DR1, thereby spraying the ink INK onto the top of the base substrate BP. When the stage STA is moved in the second direction DR2 and to be located under a base frame BF, the inkjet head 100 may be moved between the first rail RL1 and the second rail RL2 while spraying the ink INK. The operation of the inkjet head 100 is not limited thereto and may be variously modified within a range in which a similar process can be implemented.

In an embodiment, the reservoir RSV may supply the ink INK to the inkjet head 100, and the inkjet head 100 may drop (e.g., deposit) the supplied ink INK. The ink INK may be circulated in the reservoir RSV and the inkjet head 100. A portion of the ink supplied to the inkjet head 100 may be dropped from the inkjet head 100 to the base substrate BP, and the other portion of the ink may be again supplied to (e.g., returned to) the reservoir RSV.

In an embodiment, the reservoir RSV may be connected to the inkjet head 100 through a connection pipe IL. For example, the reservoir RSV may supply the ink INK to the inkjet head 100 through the connection pipe IL, and a flow rate of the supplied ink INK may be adjusted via a valve VA.

Although an embodiment in which the reservoir RSV is held by the base frame BF is illustrated, the present disclosure is not limited thereto. The reservoir RSV is provided in the inkjet printing apparatus 1000, and the position and/or form of the reservoir RSV is not particularly limited. For example, the reservoir RSV may be disposed through a separate apparatus and may be variously disposed within a range in which the reservoir RSV is connected to the inkjet head 100.

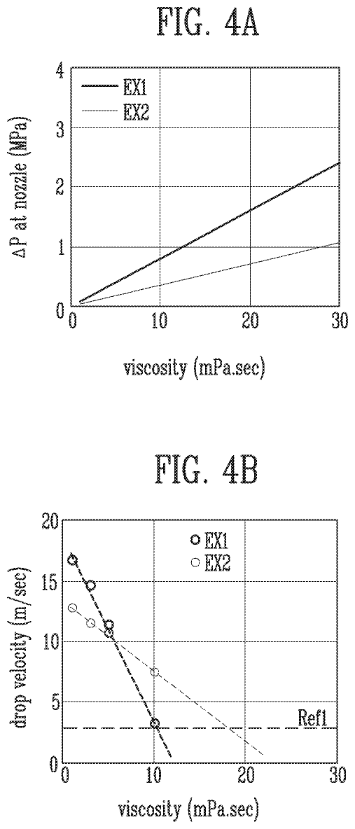

FIG. 3 is a sectional view illustrating an inkjet head 10 in accordance with a comparative example. FIG. 4A is a graph showing pressure loss in a nozzle according to viscosity of an ink, and FIG. 4B is a graph showing drop in velocity of the ink according to viscosity of the ink.

The inkjet head 10 according to a comparative example may include an ink heating part 16 and an ink supply part 17.

The ink supply part 17 may include a common ink chamber 12 and a pressure chamber 14. In an example, the common ink chamber 12 is a path through which an ink is introduced from an ink reservoir, and the pressure chamber 14 is a place (e.g., a space) in which the ink INK to be dropped is filled and may be disposed at one side or both sides of the common ink chamber 12.

The common ink chamber 12 may be supplied with the ink INK from the ink reservoir through an ink supply hole (e.g., an ink supply opening) 11, and the ink INK in the common ink chamber 12 may be supplied to the pressure chamber 14 through an ink supply hole (e.g., an ink supply opening) 13. The ink INK filled in the pressure chamber 14 may be dropped through (e.g., deposited through) a nozzle 15.

The ink INK may include a solvent SL and a light emitting element LD.

In an embodiment, the light emitting element LD may be included in the solvent SL in a state in which the light emitting element LD is dispersed in the solvent SL to be dropped through the nozzle 15 of the inkjet head 10.

In an embodiment, the light emitting element LD may be dropped as a droplet in the form of an ink drop through the nozzle 15 of the inkjet head 10 in a state in which the light emitting element LD is dispersed in the solvent SL.

Referring to FIGS. 4A and 4B, a first example EX1 represents pipe friction loss ΔP of the nozzle (hereinafter, referred to as pipe friction loss) and drop velocity of the ink INK according to viscosity of the ink INK when the diameter of the nozzle is about 20 μm. A second example EX2 represents pipe friction loss ΔP and drop velocity of the ink INK according to viscosity of the ink INK when the diameter of the nozzle is about 30 μm.

Referring to FIG. 4A, as the viscosity of the ink INK increases, the pipe friction loss of the nozzle increases. In addition, as the diameter of the nozzle decreases, the pipe friction loss of the nozzle increases.

Referring to FIG. 4B, as the viscosity of the ink INK increases, the drop velocity of the ink INK decreases. As the diameter of the nozzle decreases, the drop velocity of the ink INK decreases. That is, the drop velocity of the ink INK decreases, the drop stability of the ink INK may be reduced.

In an embodiment, as the diameter of the nozzle 15 decreases, the viscosity of the ink dropped from the nozzle below a drop lower limit velocity Ref1 is considered to be relatively low. In an example, the viscosity of the ink INK dropped from the nozzle of the first example EX1 at or below the drop lower limit velocity Ref1 of the ink INK may be lower than the viscosity of the ink INK dropped from the nozzle of the second example EX2.

The inkjet head 10 in accordance with the comparative example includes the ink heating part 16, and the ink heating part 16 may be disposed in the ink supply part 17, thereby entirely heating the ink INK filled in the ink supply part 17. As a result, the pipe friction loss is reduced or minimized by lowering the viscosity of the ink INK. Thus, the drop velocity of the ink INK is not decreased (or is not substantially decreased), thereby ensuring the drop stability of the ink INK.

Stokes' law provides an expression capable of predicting a particles' settling velocity Vs in an arbitrary fluid. Stokes' law is influenced by particle diameter d, a true density Pp of particles, a true density Pf of the fluid, gravitational acceleration g, and a viscosity μ of the fluid. According to Stokes' law, the settling velocity increases as a true density difference between the particles and the fluid and the diameter of the particles increase and as the viscosity of the fluid decreases.

When the ink INK in the ink supply part 17 is entirely heated by the ink heating part 16, the inkjet head 10 in accordance with the comparative example may lower the viscosity of the ink INK. As a result, the particles' settling velocity in the ink INK is increased.

The temperature of the ink INK included in the ink supply part 17 may be increased by the ink heating part 16 and the viscosity of the ink INK may be lowered. Accordingly, the settling velocity of the light emitting element LD in the ink INK is increased, and therefore, the dispersibility of the light emitting element LD may be lowered.

When the common ink chamber 12 and the pressure chamber 14 are heated by the ink heating part 16, the temperature of the ink INK in the ink supply part 17 is raised, and therefore, the ink INK in the ink supply part 17 has a low viscosity characteristic.

As the viscosity of the ink INK in the common ink chamber 12 is lowered, the settling velocity of the light emitting element LD included in the ink INK may increase. At least some of light emitting elements LD included in the ink INK in the common ink chamber 12 do not move to the pressure chamber 14 but may accumulate in the common ink chamber 12. At least a portion of the ink INK in the common ink chamber 12 may be moved to the pressure chamber 14. As the settling velocity of the light emitting element LD increases, the quantity of light emitting elements LD accumulated in the common ink chamber 12 may increase.

The ink INK may be filled in the pressure chamber 14 through the ink supply hole 13 connected to the common ink chamber 12. As the viscosity of the ink INK in the pressure chamber 14 is reduced, the settling speed of the light emitting element LD included in the ink INK may increase. At least some of light emitting elements LD in the ink INK in the pressure chamber 14 do not drop through the nozzle 15 but may be accumulated in the pressure chamber 14.

That is, when the dispersibility of the light emitting element LD in the ink INK is reduced, it is difficult to ensure the uniformity of the ink INK dropped through the nozzle 15. When the uniformity of the ink INK is reduced, it may be difficult to maintain a uniform number of light emitting elements LD in the ink INK.

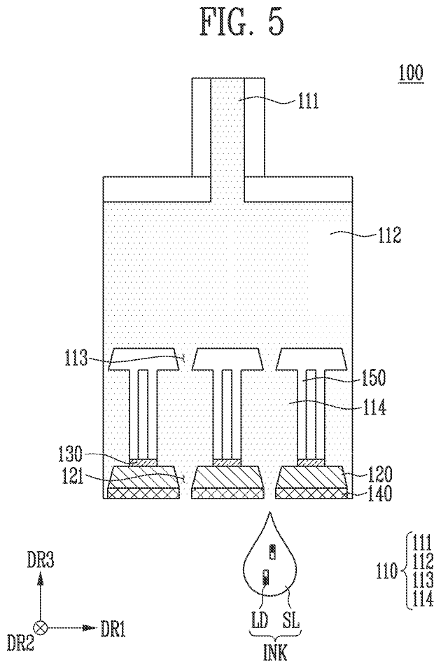

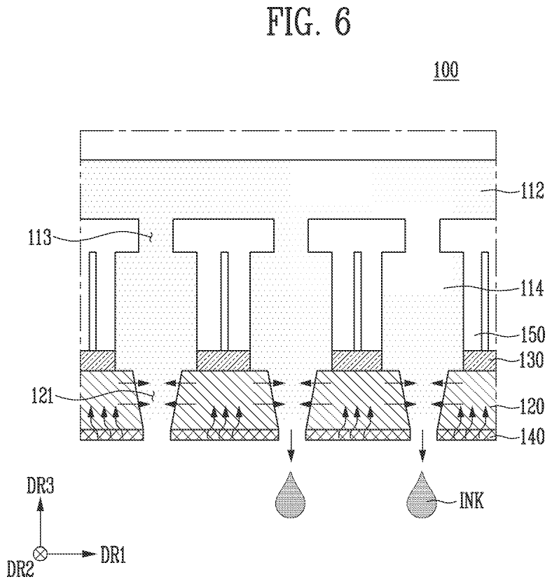

FIG. 5 illustrates an example of an inkjet head 100 in accordance with an embodiment of the present disclosure, and FIG. 6 illustrates an example of driving of the inkjet head 100 shown in FIG. 5.

Referring to FIGS. 5 and 6, the inkjet head 100 may include an ink supply part 110, a nozzle plate 120, an insulation member 130, a nozzle plate heating part (e.g., a nozzle plate heater) 140, and a pressure actuator 150.

In an embodiment, the ink supply part 110 may include a common ink chamber 112, a pressure chamber 114, a first ink supply hole (e.g., a first ink supply opening) 111, and a second ink supply hole (e.g., a second ink supply opening) 113.

In an embodiment, the common ink chamber 112, the pressure chamber 114, the first ink supply hole 111, and the second ink supply hole 113 correspond to a space through which an ink INK passes before the ink INK is transferred to a nozzle 121 formed in the nozzle plate 120.

In an embodiment, the ink INK may be supplied and filled in the ink supply part 110 through the first ink supply hole 111 from an ink reservoir (e.g., the reservoir RSV shown in FIG. 1). In an example, the ink INK may be supplied and filled in the common ink chamber 112 through the first ink supply hole 111.

In an embodiment, the common ink chamber 112 is used to supply the ink INK to a plurality of pressure chambers 114 and corresponds to a common ink flow path through which the ink INK passes before the ink INK is supplied to the plurality of pressure chambers 114.

In an embodiment, the common ink chamber 112 may be connected to the plurality of pressure chambers 14 through the second ink supply hole 113. The pressure chamber 114 is filled with the ink INK through the second ink supply hole 113 from the common ink chamber 112. In an example, the inkjet printing apparatus 1000 may include a restrictor for adjusting an amount of the ink INK at a position adjacent to the second ink supply hole 113.

In an embodiment, the pressure chamber 114 may have a structure in which the second ink supply hole 113 is connected to one end thereof and the nozzle 121 is connected to the other end thereof.

In an embodiment, the ink INK filled in the pressure chamber 114 through the second ink supply hole 113 from the common ink chamber 112 may be dropped through the nozzle 121 formed in the nozzle plate 120 connected to the pressure chamber 114.

In an embodiment, the inkjet head 100 may include the pressure actuator 150 to correspond to the pressure chamber 114. In an example, the pressure actuator 150 may be disposed to surround the pressure chamber 114. In an example, the pressure actuator 150 may be disposed on the insulation member 130, which will be described in more detail later. In an example, the pressure actuator 150 may be a structure disposed in the ink supply part 110 to partition the plurality of pressure chambers 114. In an example, the nozzle plate 120 forming the nozzle 121 may be disposed on a bottom surface of the pressure actuator 150 disposed in the ink supply part 110.

In an embodiment, the pressure actuator 150 may provide a driving force for dropping the ink INK in the pressure chamber 114. The pressure actuator 150 may provide a pressure change to (e.g., may pressurize) the pressure chamber 114. In an example, the pressure actuator 150 may vibrate the ink INK inside the pressure chamber 114 and the nozzle 121.

In an example, the ink INK filled in the pressure chamber 114 may be dropped through the nozzle 121 formed in the nozzle plate 120 due to the pressure change of the pressure chamber 114, which is caused by the pressure actuator 150.

In an embodiment, the pressure actuator 150 may include at least one of a piezoelectric actuator, a piezoelectric element, a linear resonant actuator (LRA), and an eccentric rotating mass (ERM), but the present disclosure is not limited thereto. The LRA may include an actuator for generating vibration by using a resonant phenomenon made by a balance weight, a spring, and a coil. The ERM may include an actuator for generating vibration by allowing an eccentric mass to be rotated by a driving voltage.

In an embodiment, the nozzle plate 120 may disposed at a lower portion of the ink supply part 110. In an example, the nozzle plate 120 may be disposed on the bottom of the pressure actuator 150. The nozzle 121 formed in the nozzle plate 120 may be disposed to be connected to the plurality of pressure chambers 114.

In an embodiment, the nozzle plate 120 may include a material having a high thermal conductivity. For example, the nozzle plate 120 may include at least one of stainless steel (e.g., SUS304), aluminum (e.g., A3004), and magnesium (e.g., AZ91D).

In an embodiment, the ink INK dropped through the nozzle 121 may include a solvent SL and a light emitting element LD. The ink INK may be provided in a solution or colloid state. For example, the solvent SL may be acetone, water (H₂O), alcohol, toluene, propylene glycol (PG), propylene glycol methyl acetate (PGMA), or the like, but the present disclosure is not limited thereto.

In another example, the ink INK dropped through the nozzle 121 may include the solvent and a functional material and/or a functional substance having a relatively low solubility. In an example, the functional material may include at least one of a conductor metal particle, a metal nano particle, a pigment, and a light conversion particle (e.g., a quantum dot nano particle). The functional material may be used as a pigment for printing a paper or building material or a material which patterns a fine line or constitutes a color filter or a light emitting element of a display device.

In an embodiment, the light emitting element LD may be included in a state in which the light emitting element LD is dispersed in the solvent SL to be dropped through the nozzle 121.

In an embodiment, the light emitting element LD may be dropped as a droplet in the form of an ink drop on a base substrate (e.g., the base substrate BP shown in FIG. 1) through the nozzle 121 of the nozzle plate 120 in a state in which the light emitting element LD is dispersed in the solvent SL.

In an embodiment, the light emitting element LD may include a first semiconductor layer, a second semiconductor layer, and an active layer interposed between the first semiconductor layer and the second semiconductor layer. In an example, the light emitting element LD may be implemented as a light emitting stack structure (or stack pattern) in which the first semiconductor layer, the active layer, and the second semiconductor layer are sequentially stacked.

Drop stability according to a drop velocity of the ink INK and dispersibility of the light emitting element LD included in the ink INK passing through the ink supply part 110 are to be ensured such that the light emitting element LD in the ink INK dropped through the nozzle 121 is disposed in a uniform concentration on the base substrate BP. To this end, the inkjet head 100 may include the insulation member 130 and the nozzle plate heating part 140.

In an embodiment, the nozzle plate heating part 140 may heat the nozzle plate 120. When the nozzle plate heating part 140 is operated to heat the nozzle plate 120, heat may be transferred to the nozzle 121 formed in the nozzle plate 120. When the heat is transferred to the nozzle 121, the temperature of the ink INK dropped through the nozzle 121 is increased, and therefore, the viscosity of the ink INK dropped through the nozzle 121 may be reduced. When the viscosity of the ink INK dropped through the nozzle 121 is reduced, the pipe friction loss of the nozzle 121 is relatively decreased, and therefore, the drop velocity of the ink INK may relatively increase. As a result, the ink INK can be stably dropped from the nozzle 121.

In an example, the nozzle plate heating part 140 may be disposed adjacent to the nozzle plate 120. In an example, the nozzle plate heating part 140 may be (e.g., may be at or may form) one surface of the nozzle plate 120 (e.g., in the third direction DR3). Although it is illustrated that the nozzle plate heating part 140 is disposed on a bottom surface of the nozzle plate 120, the present disclosure is not limited thereto. For example, the nozzle plate heating part 140 may be disposed on a top surface of the nozzle plate 120 in which the nozzle 121 is formed.

In an embodiment, the nozzle plate heating part 140 may include at least one of a heater, an induction heating device, an element having an electrode, and a Peltier module. However, the present disclosure is not limited thereto, and the nozzle plate heating part 140 may include a device and a circuit that is configured to heat the nozzle plate 120 through an exothermic reaction. Examples of the nozzle plate heating part 140 will be described with reference to FIGS. 8 to 11.

In an embodiment, heat may be transferred to the ink INK adjacent to the nozzle plate 120 by heating the nozzle plate 120. The inkjet head 100 may include the insulation member 130 to block heat from being transferred to the common ink chamber 112, the pressure chamber 114, and the second ink supply hole 113. In an example, the insulation member 130 may be disposed between the nozzle plate 120 and the ink supply part 110. In an example, the insulation member 130 may be disposed between the nozzle plate 120 and the pressure actuator 150. The insulation member 130 may block (or substantially block) heat from being transferred to the pressure chamber 114 and the common ink chamber 112, which are disposed above the insulation member 130. Thus, the heat generated by the nozzle plate heating part 140 is not transferred to the entire inkjet head 100 but may be transferred to only the nozzle plate 120 due to the insulation member 130 disposed on the top of the nozzle plate 120.

Before the ink INK is moved to the nozzle 121 formed in the nozzle plate 120, the viscosity of the ink INK filled in the common ink chamber 112, the pressure chamber 114, and the second ink supply hole 113 may be maintained at a reference level or more because the heat is transferred to only the nozzle plate 120. Thus, the dispersibility of the light emitting element LD included in the ink INK filled in the common ink chamber 112, the pressure chamber 114, and the second ink supply hole 113 is not deteriorated so that the density of the light emitting element LD is maintained during a process in which the ink INK is moved to the nozzle 121 from the common ink chamber 112.

In an embodiment, the insulation member 130 may include a material having a low thermal conductivity. For example, the insulation member 130 may include at least one of glass, epoxy, and silica fiber. In an example, the nozzle plate 120 may include a thermal conductive material. In an example, the thermal conductivity of the insulation member 130 may be lower than a thermal conductivity of the nozzle plate 120.

In an embodiment, heat may be blocked (or substantially blocked) from being transferred to the common ink chamber 112, the pressure chamber 114, and the second ink supply hole 113, thereby preventing the viscosity of the ink INK passing through the common ink chamber 112, the pressure chamber 114, and the second ink supply hole 113 from being lowered. When the viscosity of the ink INK passing through the ink supply part 110 is reduced due to an increase in temperature, the dispersibility of the light emitting element LD included in the ink INK is not deteriorated. For example, heat transferred to the ink supply part 110 through the insulation member 130 is blocked, thereby decreasing the number of light emitting elements LD which do not pass through the nozzle 121 but are accumulated in the ink supply part 110.

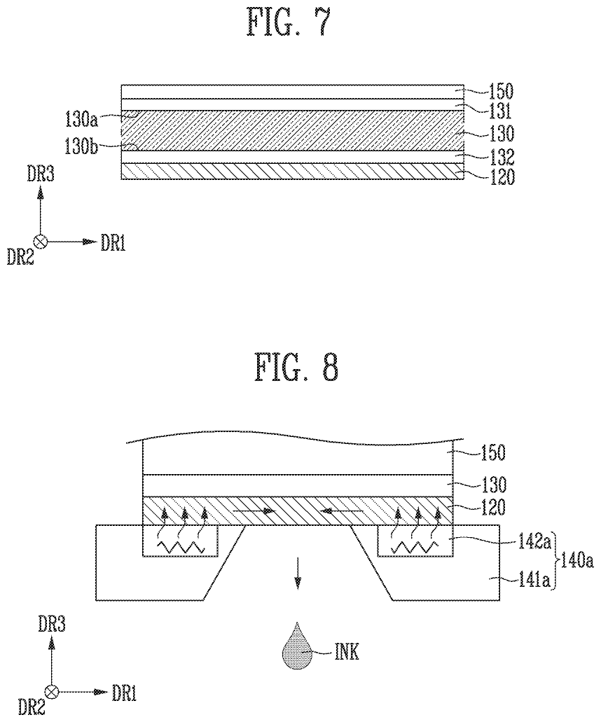

FIG. 7 illustrates an example of the insulation member 130 included in the inkjet head 100 shown in FIG. 5.

Referring to FIG. 7, the insulation member 130 may be disposed on the top of the nozzle plate 120. In an example, the insulation member 130 may be disposed between the nozzle plate 120 and the ink supply part 110. In an example, the insulation member 130 may be disposed between the nozzle plate 120 and the pressure actuator 150 disposed in the ink supply part 110. The insulation member 130 may prevent heat from being transferred (e.g., directly transferred) to the ink supply part 110 adjacent to the nozzle plate 120 that is heated by a nozzle plate heating part (e.g., the nozzle plate heating part 140 shown in FIG. 5).

In an embodiment, the insulation member 130 may include a first surface 130a facing the pressure actuator 150 and a second surface 130b facing the nozzle plate 120.

In an embodiment, the insulation member 130 may include at least one of glass and silica fiber.

In an embodiment, a first adhesive insulator 131 may be disposed on the first surface 130a of the insulation member 130. In an example, the first adhesive insulator 131 may be disposed between the insulation member 130 and the pressure actuator 150. The insulation member 130 may be attached to the bottom surface of the pressure actuator 150 by the first adhesive insulator 131.

In an embodiment, a second adhesive insulator 132 may be disposed on the second surface 130b of the insulation member 130. In an example, the second adhesive insulator 132 may be disposed between the insulation member 130 and the nozzle plate 120. The insulation member 130 may be attached to the top surface of the nozzle plate 120 by the second adhesive insulator 132.

In an embodiment, the first adhesive insulator 131 and the second adhesive insulator 132 may include an epoxy adhesive. However, the present disclosure is not limited thereto, and the first adhesive insulator 131 and the second adhesive insulator 132 may include an adhesive including a material having insulation and adhesive properties (e.g., adhesion functions).

In an example, the insulation member 130 may prevent the heat transferred to the nozzle plate 120 from being transferred to the ink INK included in an ink supply part (e.g., the ink supply part 110 shown in FIG. 5) disposed above the insulation member adjacent to the nozzle plate 120. In an example, the insulation member 130 may block the heat transferred from the nozzle plate 120 from being transferred to the common ink chamber 112, the second ink supply hole 113, and/or the pressure chamber 114, which are adjacent to the nozzle plate 120.

FIG. 8 illustrates an example of the nozzle plate heating part included in the inkjet head 100 shown in FIG. 5.

Referring to FIG. 8, a nozzle plate heating part 140a may include a heater 142a and a frame 141a.

In an embodiment, the frame 141a may provide a space in which the heater 142a is mounted. The frame 141a may be disposed on a bottom surface of the nozzle plate heating part 140a to support the heater 142a and to guide an ink INK to be stably dropped on a substrate (e.g., the base substrate BP shown in FIG. 1) from a nozzle (e.g., the nozzle 121 shown in FIG. 5).

In an embodiment, the heater 142a may be a rectangular plate. The heater 142a may be a ceramic heater including an electrical resistance heating wire. The heater 142a may be mounted in the frame 141a to be disposed on the bottom surface of the nozzle plate 120.

In an embodiment, heat may be generated by an operation of the heater 142a. The heat generated by the heater 142a may be transferred to the nozzle plate 120. The temperature of the ink INK passing through the nozzle 121 formed in the nozzle plate 120 may be raised by the heat transferred to the nozzle plate 120.

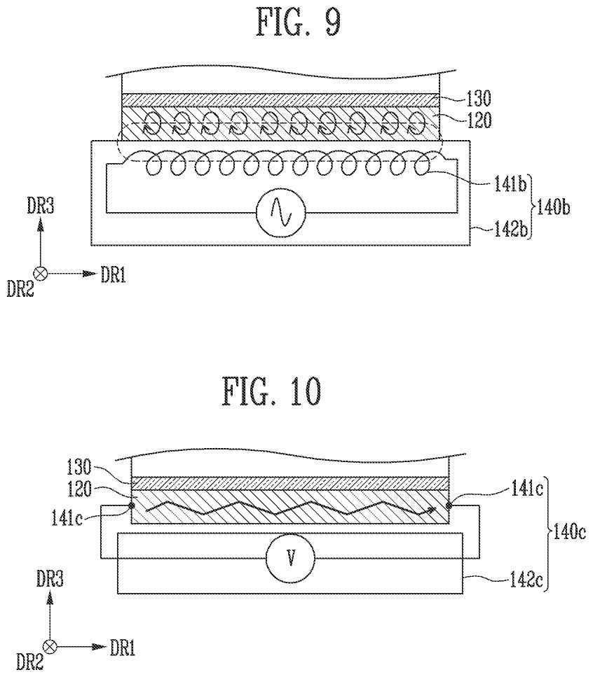

FIG. 9 illustrates another example of the nozzle plate heating part included in the inkjet head 100 shown in FIG. 5.

Referring to FIG. 9, a nozzle plate heating part 140b may include an induction heating device. In an example, the nozzle plate heating part 140b may include a coil 141b and a coil control part 142b. The nozzle plate heating part 140b may heat the nozzle plate 120 by using an eddy current generated by electromagnetic induction and electrical resistance. In an embodiment, in the nozzle plate heating part 140b, when current flows in the coil 141b through the coil control part 142b, a line of magnetic force may be formed at the periphery of the coil 141b, an induction current may be generated by the line of magnetic force, and the nozzle plate 120 may be heated by an interaction with resistance.

FIG. 10 illustrates another example of the nozzle plate heating part included in the inkjet head 100 shown in FIG. 5.

Referring to FIG. 10, a nozzle plate heating part 140c may include an electrode 141c and an electrode control part 142c.

In an embodiment, the electrode 141c may be attached to both ends of the nozzle plate 120. The electrode control part 142c may be connected to the electrode 141c to apply power to the electrode 141c. As the power is applied through the electrode 141c, the nozzle plate heating part 140c and the nozzle plate 120 may be electrically connected to each other, and Joule heating may be generated by the electrical connection. The nozzle plate 120 may be heated by the generated Joule heating.

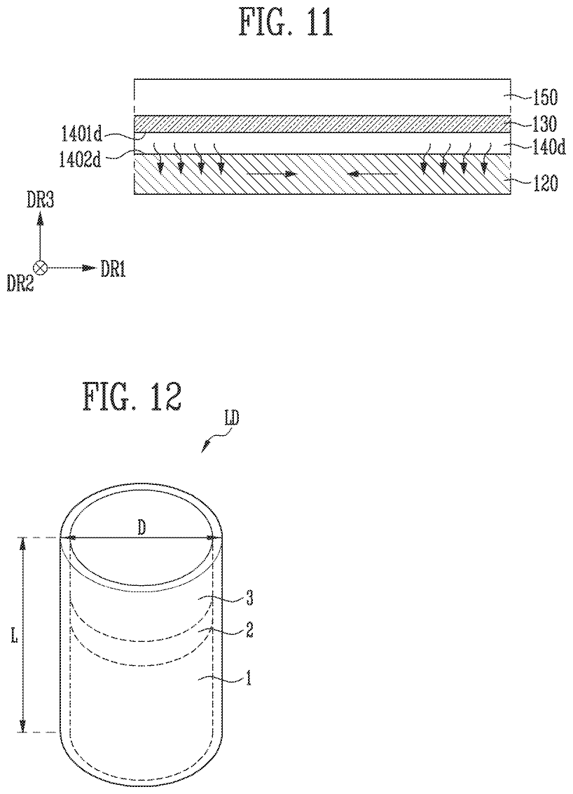

FIG. 11 illustrates another example of the nozzle plate heating part included in the inkjet head 100 shown in FIG. 5.

Referring to FIG. 11, a nozzle plate heating part 140d may include a Peltier module using a Peltier effect. In an example, in the Peltier module, when current flows as two kinds of metals are connected to each other, an exothermic reaction or an endothermic reaction may occur at a joint between the two metals. To carry electrons to a metal in a state in which potential energy is high by using a difference between potential energies of electrons in the two kinds of metals, heat is absorbed at a point of contact to obtain energy from the outside. In the contrary case, heat is released.

In an embodiment, the nozzle plate heating part 140d may be disposed on the top surface of the nozzle plate 120. In an example, the nozzle plate heating part 140d may include a first surface 1401d at which the endothermic reaction occurs and a second surface 1402d at which the exothermic reaction occurs. In an example, the first surface 1401d may be a low temperature surface at which the endothermic reaction occurs, and the second surface 1402d may be a high temperature surface at which the exothermic reaction occurs.

In an embodiment, the second surface 1402d of the nozzle plate heating part 140d may be disposed to face the nozzle plate 120. The first surface 1401d of the nozzle plate heating part 140d may be disposed to face the insulation member 130.

In an embodiment, when power is applied to the nozzle plate heating part 140d, the exothermic reaction may occur at the second surface 1402d, and the endothermic reaction may occur at the first surface 1401d. The nozzle plate 120 may be heated through heat generated at the second surface 1402d. Heat can be blocked from being conducted in a direction in which an ink supply part (e.g., the ink supply part 110 shown in FIG. 5) is disposed through the exothermic reaction occurring at the first surface 1401d.

FIG. 12 is a view illustrating an example of the light emitting element LD included in the ink INK dropped from the nozzle 121 shown in FIG. 5.

In an embodiment, referring to FIG. 12, a light emitting element LD may include a first semiconductor layer 1, a second semiconductor layer 3, and an active layer 2 interposed between the first semiconductor layer 1 and the second semiconductor layer 3. In an example, the light emitting element LD may be implemented with a light emitting stack structure (or stack pattern) in which the first semiconductor layer 1, the active layer 2, and the second semiconductor layer 3 are sequentially stacked.

In an embodiment, the light emitting element LD may have a rod-like shape, a bar-like shape, or a pillar-like shape, which is long in its length direction (e.g., its aspect ratio is greater than 1). However, the present disclosure is not limited thereto, and the light emitting element LD may have a rod-like shape, a bar-like shape, or a pillar-like shape, which is short in its length direction (e.g., its aspect ratio is smaller than 1).

In an embodiment, the light emitting element LD may have a diameter D and/or a length L to a degree of nanometer scale (or nanometer) to micrometer scale (micrometer). The light emitting element LD may include a light emitting diode (LED) manufactured to be subminiature. For example, when the light emitting element LD is long in its length direction, the diameter D of the light emitting element LD may be about 0.5 μm to about 6 μm, and the length L of the light emitting element LD may be about 1 μm to about 10 μm. However, the diameter D and the length L of the light emitting element LD are not limited thereto, and the size of the light emitting element LD may be varied to accord with requirement conditions (or design conditions) of a lighting device or a self-luminous display device to which the light emitting element LD is to be applied.

In an embodiment, the first semiconductor layer 1 may include at least one n-type semiconductor layer. For example, the first semiconductor layer 1 may include any one semiconductor material from among InAlGaN, GaN, AlGaN, InGaN, AlN, and InN. The first semiconductor layer 1 may be an n-type semiconductor layer doped with a first conductive dopant (or n-type dopant), such as silicon (Si), germanium (Ge) or tin (Sn). However, the material (or substance) constituting the first semiconductor layer 1 is not limited thereto. In addition, the first semiconductor layer 1 may include various suitable materials. The first semiconductor layer 1 may have a first surface in contact with the active layer 2 along the length direction of the light emitting element LD and a second surface exposed to the outside.

In an embodiment, the active layer 2 is formed on the first semiconductor layer 1 and may be formed to have a single or multiple quantum well structure. When the active layer 2 is formed to have the multiple quantum well structure, the active layer 2 may be formed by periodically and repeatedly stacking a barrier layer, a strain reinforcing layer, and a well layer, which constitute one unit. The strain reinforcing layer may have a lattice constant smaller than a lattice constant of the barrier layer and may apply compressive strain to the well layer. However, the structure of the active layer 2 is not limited to the above-described embodiment.

In an embodiment, the active layer 2 may emit light having a wavelength in a range of about 400 nm to about 900 nm. The active layer 2 may use a double hetero structure. In an example, a clad layer doped with a conductive dopant may be formed on the top and/or the bottom of the active layer 2 along the length direction of the light emitting element LD. In an example, the clad layer may be formed as an AlGaN layer or InAlGaN layer. A material, such as AlGaN or AlInGaN, may be used to form the active layer 2. In addition, various suitable materials may be included in the active layer 2. The active layer 2 may include a first surface in contact with the first semiconductor layer 1 and a second surface in contact with the second semiconductor layer 3.

In an embodiment, when an electric field having a reference voltage (e.g., a predetermined voltage) or more is applied to both end portions (e.g., opposite end portions) of the light emitting element LD, the light emitting element LD emits light as electron-hole pairs are combined in the active layer 2. The light emitting element LD may be used as a light source (or light emitting source) for a display device.

In an embodiment, the second semiconductor layer 3 is formed on the second surface of the active layer 2 and may include a semiconductor layer having a type different from the type of the first semiconductor layer 1. In an example, the second semiconductor layer 3 may include at least one p-type semiconductor layer. For example, the second semiconductor layer 3 may include at least one semiconductor material from among InAlGaN, GaN, AlGaN, InGaN, AlN, and InN and may include a p-type semiconductor layer doped with a second conductive dopant (or p-type dopant), such as magnesium (Mg), zinc (Zn), calcium (Ca), strontium (Sr) or barium (Ba). However, the second semiconductor layer 3 is not limited thereto. In addition, the second semiconductor layer 3 may include various suitable materials. The second semiconductor layer 3 may have a first surface in contact with the second surface of the active layer 2 and a second surface exposed to the outside along the length direction of the light emitting element LD.

In the inkjet head and the inkjet printing apparatus including the same in accordance with embodiments of the present disclosure, an ink including light emitting elements can be stably dropped through a nozzle. Also, in the inkjet head and the inkjet printing apparatus including the same in accordance with embodiments of the present disclosure, uniform dispersibility of the light emitting elements in the ink provided to the nozzle can be ensured, and the ink containing a uniform number of light emitting elements can be dropped.

Example embodiments have been disclosed herein, and although specific terms are employed, they are used and are to be interpreted in a generic and descriptive sense and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth in the following claims and their equivalents.

What is claimed is:

1. An inkjet head comprising:
an ink supply part configured to supply an ink;
a nozzle plate connected to the ink supply part and having a nozzle configured to drop the ink provided from the ink supply part;
a nozzle plate heating part adjacent to the nozzle plate and configured to heat the nozzle plate; and
an insulation member between the nozzle plate and the ink supply part.

2. The inkjet head of claim 1, further comprising a first adhesive insulator between the nozzle plate and the insulation member.

3. The inkjet head of claim 2, further comprising a pressure actuator in the ink supply part and configured to vibrate the ink in the nozzle.

4. The inkjet head of claim 2, further comprising a second adhesive insulator between the insulation member and the ink supply part.

5. The inkjet head of claim 4, wherein the first adhesive insulator and the second adhesive insulator comprise an epoxy adhesive.

6. The inkjet head of claim 1, wherein the insulation member includes at least one of glass and silica fiber.

7. The inkjet head of claim 1, wherein the nozzle plate heating part comprises a heater on one surface of the nozzle plate.

8. The inkjet head of claim 1, wherein the nozzle plate heating part comprises a Peltier module between the nozzle plate and the insulation member.

9. The inkjet head of claim 8, wherein a low temperature surface of the Peltier module faces the insulation member, and a high temperature surface of the Peltier module faces the nozzle plate.

10. The inkjet head of claim 1, wherein the nozzle plate heating part comprises an induction heating device on a bottom surface of the nozzle plate, the induction heating device comprising a coil.

11. The inkjet head of claim 1, wherein the nozzle plate heating part comprises:
electrode terminals electrically connected to the nozzle plate; and
an electrode control part configured to apply power to the electrode terminals.

12. The inkjet head of claim 1, wherein the ink comprises at least one of a light emitting element, a conductor metal particle, and a light conversion particle, and
wherein the light emitting element comprises a first semiconductor layer, a second semiconductor layer, and an active layer between the first semiconductor layer and the second semiconductor layer.

13. The inkjet head of claim 1, wherein the nozzle plate comprises a conductive material, and
wherein a thermal conductivity of the insulation member is lower than a thermal conductivity of the nozzle plate.

14. An inkjet printing apparatus comprising:
a stage configured to receive a substrate thereon;
an inkjet head configured to drop ink on the substrate; and
a reservoir configured to store the ink,
wherein the inkjet head comprises:
an ink supply part configured to be supplied with the ink from the reservoir;
a nozzle plate connected to the ink supply part and having a nozzle configured to drop the ink provided from the ink supply part;
a nozzle plate heating part adjacent to the nozzle plate and configured to heat the nozzle plate; and
an insulation member between the nozzle plate and the ink supply part.

15. The inkjet printing apparatus of claim 14, further comprising a pressure actuator in the ink supply part and configured to vibrate the ink in the nozzle.

16. The inkjet printing apparatus of claim 14, further comprising:
a first adhesive insulator between the nozzle plate and the insulation member; and
a second adhesive insulator between the insulation member and the ink supply part.

17. The inkjet printing apparatus of claim 16, wherein the first adhesive insulator and the second adhesive insulator comprise an epoxy adhesive.

18. The inkjet printing apparatus of claim 14, wherein the nozzle plate heating part comprises a heater on one surface of the nozzle plate.

19. The inkjet printing apparatus of claim 14, wherein the nozzle plate heating part comprises an induction heating device having a coil.

20. The inkjet printing apparatus of claim 14, wherein the nozzle plate heating part comprises a Peltier module between the nozzle plate and the insulation member.
